(19) United States
(12) Patent Application Publication
(10) Pub. No.: US 2003/0094939 A1
(43) Pub. Date: May 22, 2003

(54) Electronic devices mounted on electronic equipment board test system and test method

(75) Inventor: Hajime Matsuzawa, Tokyo (JP)

Correspondence Address: YOUNG & THOMPSON, 745 SOUTH 23RD STREET 2ND FLOOR, ARLINGTON, VA, 22202

(73) Assignee: NEC CORPORATION, Tokyo (JP)

(21) Appl. No.: 10/281,956

(22) Filed: Oct. 29, 2002

(30) Foreign Application Priority Data
Nov. 22, 2001 (JP) 2001-356846

(51) Int. Cl. G01R 1/00

(52) U.S. Cl. 324/158.1

(57) ABSTRACT

An electronic device test system includes electronic equipment having a board on which pluralities of electronic devices are mounted and isolation means which isolates from surrounding air an electronic device to be tested. When executing an electronic device test, the electronic device to be tested, which is one of the plurality of electronic devices mounted on the board of the electronic equipment, is isolated from surrounding air by the isolation means. After that, a power supply voltage is applied to the electronic equipment and an electric signal is applied to the electronic device for testing the electronic device.

### BACKGROUND OF THE INVENTION

The present invention relates to an electronic device test where a burn-in test is made, and more particularly to an electronic device test where a burn-in test is made for an electronic device which is mounted on electronic equipment.

A burn-in test is commonly made as one of screening processes of an electronic device. The burn-in test refers to a test in which an electronic device is turned on at a high temperature to check for a fault or a failure of the electronic device. Because an electronic device, if turned on at a high temperature, deteriorates more rapidly than in a running at a normal temperature, a fault or a failure, which may cause an early failure, is forced to occur in a short time.

In a conventional burn-in test, a test object is inserted into a socket on a test board called a burn-in board. The burn-in board, in which the test object is inserted, is stored in a constant temperature bath called a burn-in test bath. Then, the inside of the burn-in test bath is heated to a predetermined temperature, and an electronic signal is applied to test the test object.

The conventional burn-in test described above requires a constant temperature bath in order to create a high-temperature environment. The constant temperature bath used for a burn-in test must be large enough for storing a large number of electronic devices to be tested in one test. This requires a technology for maintaining the temperature inside the bath at a uniform temperature, making the constant temperature bath costly. In addition, the burn-in test requires two additional processes: a pre-process called “insertion” in which an electronic device to be tested is inserted into the burn-in board and a post-process called “removal” in which an electronic device for which the test is completed is removed from the burn-in board. Furthermore, an electric signal pattern used for the test must be designed so that a failure of the test and a failure of the usual running may be same. However, designing a complete electric signal test pattern is not easy because there are circuit noises in a normal running. In another way, it is also possible to assemble electronic equipment with the electronic devices into an actual use condition and then to put the whole electronic equipment in a constant temperature bath for testing. A problem of this method, however, is that only a particular electronic device or a particular board cannot be heated to a high temperature but that the parts for which the burn-in test is not desired are also heated.

### SUMMARY OF THE INVENTION

It is an object of the present invention to provide an electronic device test method and a test system that solve the problems described above.

In accordance with the test method of the present invention, an electronic device to be tested, which is one of a plurality of electronic devices mounted on the board of electronic equipment, is isolated from surrounding air. After that, a power supply voltage is applied to the board and an electric signal is applied to the electronic device for testing the electronic device.

An electronic device test system of the present invention includes electronic equipment on which a plurality of electronic devices are mounted and isolation means for isolating from surrounding air an electronic device to be tested. The electronic device to be tested is one of the plurality of electronic devices.

The above configuration of the present invention gives the following effects: (1) A constant temperature bath is not necessary. (2) The temperature of only electronic devices to be tested may be controlled. (3) Electronic equipment is built by mounting the electronic devices in a actual use condition and, then, a burn-in test may be performed for any electronic device or for the board.

### BRIEF DESCRIPTION OF THE DRAWINGS

These and other objects, features and advantages of the invention will become more fully apparent from the following detailed description taken in conjunction with accompanying drawings.

FIG. 1 is a perspective view of a board before an electronic device test according to the present invention is made.

FIG. 2 is a perspective view of the board when electronic devices are tested.

FIG. 3 is a perspective view of an embodiment of a cover.

FIG. 4 is a flowchart showing the flow of test.

### DETAILED DESCRIPTION OF THE PREFERRED EMBODIMENTS

An embodiment of the present invention will be described in detail by referring to the attached drawings.

In accordance with the present invention, the electronic devices mounted on electronic equipment assembled into an actual use condition are used in a burn-in test.

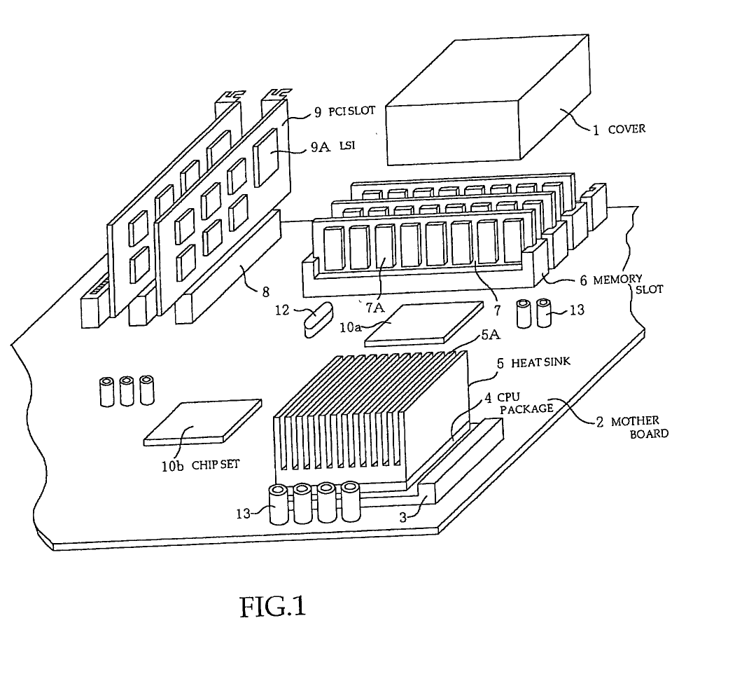

FIG. 1 shows the electronic devices to be tested, which are mounted on a mother board 2 of a computer, and a cover 1 that is used when the burn-in test is executed. When the burn-in test is executed, the cover 1 is put on the electronic devices to be tested that are mounted on the mother board 2.

On the mother board 2, a CPU (Central Processing Unit) package 4 inserted into a CPU socket 3, DIMMs (Dual Inline Memory Module) 7 inserted into memory slots 6, PCI (Peripheral Component Interconnect) extension cards 9 inserted into PCI slots 8. Furthermore, chip sets 10a and 10b, a crystal oscillator 12, an electrolytic condenser 13 and other components are mounted on the mother board 2. The CPU package 4 includes a CPU or a CPU and an L2 cache. The CPU package 4 has a heat sink 5 for radiating heat generated during CPU operation. The radiation effect is increased by sending between fins 5A a wind from a cooling fan (not shown) installed on the equipment cabinet or the fins 5A of the heat sink 5. The DIMM 7, where a plurality of memory chips 7A are mounted on one memory board, is used as the CPU work area or as the storage area of the OS (Operating System) or applications. There are many types of PCI extension card 9: graphics card that sends computer graphics data to a display, sound card that sends computer sound data to an external speaker, network card used to connect to a network, and an SCSI card used to connected to an SCSI devices such as an external storage unit. On the PCI extension card 9, a plurality of LSIs 9A are installed to achieve the purpose of the card. The chip sets 10a and 10b each control an access to each memory chip 7A in the DIMM 7 or the PCI extension card 9. The crystal oscillator 12 generates clock signals. The electrolytic condenser 13, which is a large-capacity condenser, is combined with a coil (not shown) to form a noise filter circuit that removes noise components from digital signals. Because it is difficult to use a large-capacity condenser as a surface-mounting condenser, an electrolytic condenser is used as a large-capacity condenser.

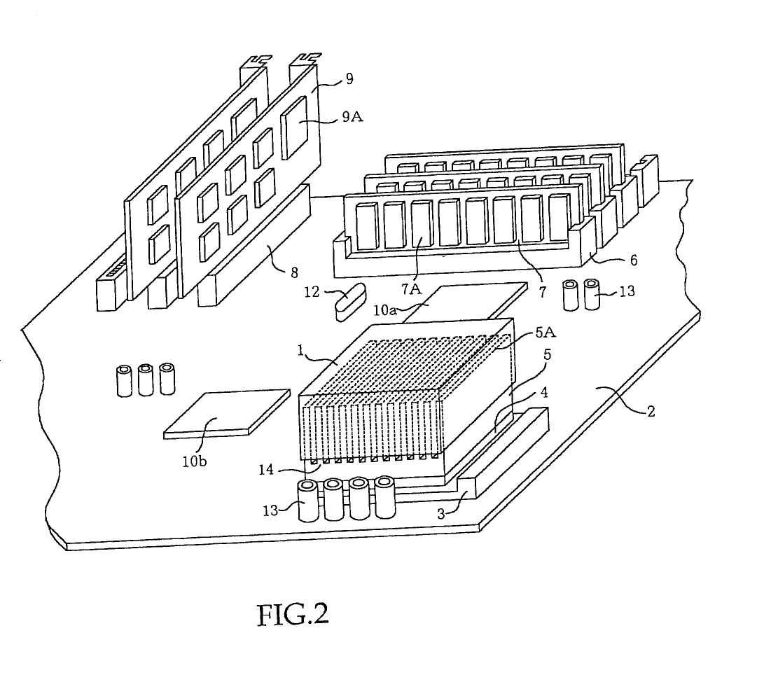

As shown in FIG. 2, the cover 1 is put on the CPU package 4 on the mother board 2 during a burn-in test. In FIG. 2, the same reference numerals in FIG. 1 denote the same structural elements. Although ceramics is used for the cover 1 in this embodiment, any low-conductivity, heat-resistant substance that stands up to about 150° C. maybe used. For a low-temperature burn-in test, the cover 1 made of resin may also be used.

The fins 5A of the heat sink 5 installed on the CPU package 4 are covered by the cover 1 for the whole longitudinal side or for the most part of the longitudinal side except a clearance 14. Putting the cover in this way significantly limits the radiation effect of the fins 5A. Therefore, even if a cool current of air from the cooling fan flows outside the cover 1, the cooling effect of the heat sink 5 is significantly reduced. If the computer runs in this state, the electric signals used for a running of the computer are input to or output from the CPU in the CPU package 4; in this case, the electric signals similar to those used for an actual running of the computer may also be input or output. Because the cooling effect of the heat sink 5 is significantly reduced, the heat generated by the CPU itself heats up the CPU to a temperature higher than that of an actual running in normal condition. The CPU is put in the high temperature state.

In a burn-in test, a test condition accurately reflecting the mechanism of an actual failure that may occur during the early failure period must be used. If the test condition does not reflect the failure mechanism accurately, a failure, which is different from the one that may occur during an actual running in normal condition, occurs and an unintended failure mechanism results. The function of the CPU is so complex that, in the conventional burn-in test, it has been difficult that an electric signal pattern that accurately reflects a failure mechanism is designed and supplied to electronic equipment. By contrast, the electronic device test method according to the present invention performs a test with an electronic device to be tested (the CPU in this embodiment) mounted on electronic equipment used in an actual use condition. This makes it possible to input or output electric signals used in an actual running or signals similar to those signals, in the test, thus making it easy to execute a test based on the failure mechanism.

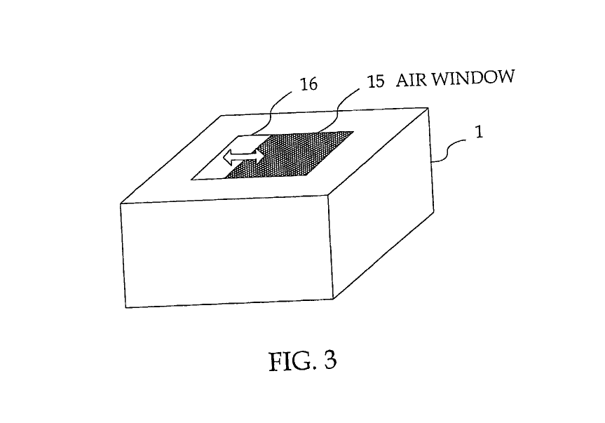

Adjusting the clearance 14 according to the heat value of the CPU to be tested allows the user to set the temperature of a device to be tested to a desired temperature. Alternatively, an air window 15 may be provided on the side or top of the cover as shown in FIG. 3. The air window 15 allows a current of air to flow through the air window to give a desired temperature. In addition, opening/closing means 16 may be provided for the air window 15 for adjusting the area of the open part of the window to adjust the flow amount of air current. This enables the user to adjust the temperature of a device more finely.

In this embodiment, no cover is put on the crystal oscillator 12 or the electrolytic condenser 13. The crystal oscillator 12 generates a clock signal with a frequency of several 10 MHz to 100 MHZ or higher. Because the CPU operates with a frequency of several 100 MHz to 1 GHz or higher in synchronization with the clock signal from the crystal oscillator 12, the frequency of this clock signal must be highly precise. Although the temperature coefficient of the oscillation frequency of a crystal oscillator is relatively small, a rise in the temperature of the crystal oscillator 12 must be prevented to make the CPU test as described above. An electrolytic condenser is a device that depends largely on the temperature of the capacity and therefore a rise in the temperature must be prevented as much as possible. That is, a rise in the temperature may lead to the leakage of electrolyte from the electrolytic condenser or, in some cases, the electrolytic condenser may blow up. These failures are caused by a mechanism quite different from that of the early failure of an electronic device. Therefore, it is desirable that a rise in the temperature of those devices be avoided during a burn-in test as much as possible. If a burn-in test is made with equipment assembled into an actual use condition in a constant temperature bath, those parts described above, which should not be heated, are also put in the high temperature state. By using cover 4, the whole board need not be put in a constant temperature bath. A rise in the temperature of a device may be prevented if the temperature rise is not needed for that device.

When a burn-in test is desired for the DIMM 7 or the chip sets 10a and 10b, the cover is also put on them. If a board has no part installed whose temperature rise must be avoided, a burn-in test may be made with one cover installed on the whole board.

Alternatively, a partition wall rather than a cover may be used to surround an electronic device to put the electronic device in a high temperature state. Any means for isolating an electronic device from the surrounding air may be used.

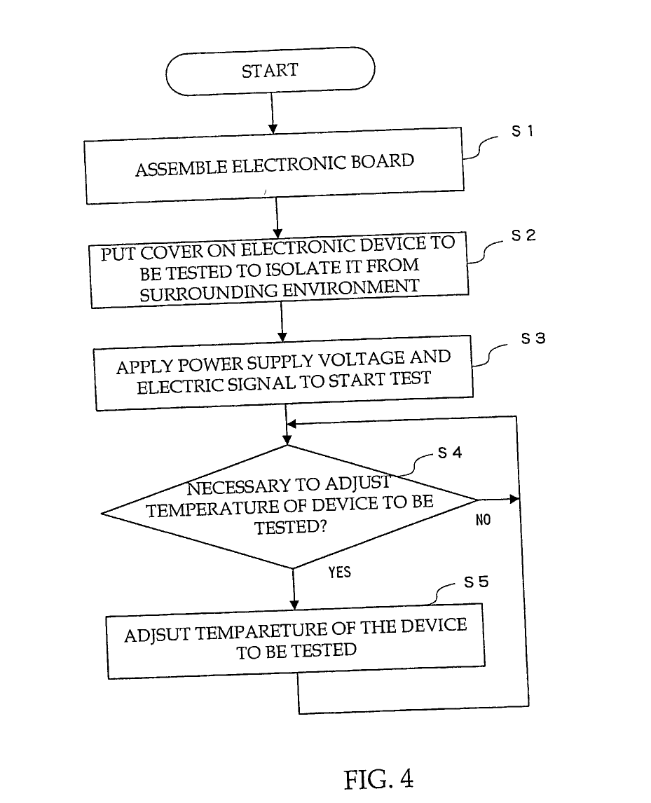

Next, the processing flow of the embodiment of the present invention will be described with reference to FIGS. 1-4. First, the electronic devices are mounted on a board to assemble the electronic equipment in the actual use state (S1 in FIG. 4). An electronic device to be tested is covered by the cover 1 to isolate it from the surrounding environment (S2). The power is applied to the board and the electric signal is applied to the electronic device to put the electronic equipment in the run state, and the resulting output signal is observed (S3) If it is required during the test to adjust the temperature for the device to be tested (or if adjustment is possible) (S4), the clearance between the cover 1 and the board is adjusted or the air-current window 15 on the cover 1 is used to adjust the temperature (S5).

As described above, the electronic device test method makes it possible to perform a burn-in test in a very low-priced facility as compared with a conventional facility. Another advantage is that the burn-in test may be made only for a desired electronic device even though other components, which are not to be tested, are mounted on equipment.

While the test method or system has been described in connection with a certain preferred embodiment, it is to be understood that the method or system is not limited to the specific embodiment described above but that all alternatives that do not depart from the spirit of the present invention are included in the scope of the present invention. For example, the electronic device test method according to the present invention may be used not only for the test of the electronic devices on a computer but also for the test of all electronic devices mounted on electronic equipment in general. The cover need not be a cube or a rectangular solid; a cover in any shape, for example, a cylinder, may be used as long as the cover may be put on an electronic device for increasing the temperature of the electronic device.

As described above, the electronic device test method according to the present invention utilizes heat generated by an electronic device to be tested, thereby eliminating the need for a costly facility such as a constant temperature bath. Therefore, as compared with the conventional method, a burn-in test may be made in a lower-priced facility.

In addition, the electronic device test method according to the present invention may be executed simply by putting a cover on an electronic device to be tested. This means that a burn-in test may be made only for a desired electronic device with that electronic device mounted on the electronic equipment.

What is claimed is:

1. A test method for testing electronic devices mounted on a board of electronic equipment, comprising the steps of:
isolating from surrounding air an electronic device to be tested, said electronic device being one of a plurality of electronic devices on the board of said electronic equipment; and
applying a power supply voltage to the board and applying an electric signal to the electronic devices for test.

2. The test method for, testing electronic devices according to claim 1,
wherein said electric signal is an electric signal applied to the electronic device during an actual use of said electronic equipment.

3. A test method for testing electronic devices mounted on a board of electronic equipment, comprising the steps of:
assembling a electronic equipment by mounting a plurality of electronic devices on the board;
putting a cover on an electronic device mounted on the board of said electronic equipment; and
applying a power supply voltage to the board and applying an electric signal to the electronic devices for test.

4. The test method for testing electronic devices according to claim 3,
wherein said electric signal is an electric signal applied to the electronic device during an actual use of said electronic equipment.

5. The test method for testing electronic devices according to claim 3,
wherein said cover is put on an electronic device to be tested, said electronic device being one of a plurality of electronic devices mounted on the board.

6. The test method for testing electronic devices according to claim 3, further comprising the step of:
adjusting a clearance provided between a bottom end of said cover and a surface of said board for adjusting a temperature of the electronic device to be tested.

7. The test method for testing electronic devices according to claim 3, further comprising the step of:
adjusting a temperature of the electronic device to be tested through an air window provided on said cover.

8. The test method for testing electronic devices according to claim 3, further comprising the step of:
changing an open area of an air window provided on said cover to change an amount of air current for adjusting a temperature of the electronic device to be tested.

9. A test system for testing electronic devices, comprising:
electronic equipment having a board on which a plurality of electronic devices are mounted; and
means for isolating from surrounding air an electronic device to be tested, said electronic device being one of said plurality of electronic devices.

10. The test system for testing electronic devices according to claim 9,
wherein there is a clearance between a bottom end of said means for isolating and a surface of said board.

11. The test system for testing electronic devices according to claim 9,
wherein said electronic device to be tested is a semiconductor device and said means for isolating prevents radiation by covering radiator provided on the semiconductor device.

12. The test system for testing electronic devices according to claim 9,
wherein said means for isolating has an air window for adjusting a temperature of the electronic device to be tested by flowing air through said air window.

13. The test system for testing electronic devices according to claim 12, further comprising:
adjustor which adjusts an open area of said air window for adjusting an amount of air current through said air window;
wherein the temperature of the electronic device is adjusted by changing said open area.
